(19) United States
(12) Patent Application Publication
(10) Pub. No.: US 2023/0003943 A1
(43) Pub. Date: Jan. 5, 2023

(54) MANUFACTURE OF SEMICONDUCTOR DEVICE WITH OPTICAL TRANSMISSION CHANNEL BETWEEN OPTICAL COUPLER AND OUTSIDE OF THE SEMICONDUCTOR DEVICE

(71) Applicant: UNITED MICROELECTRONICS CENTER CO., LTD, Chongqing (CN)

(72) Inventors: Jiguang Zhu, Chongqing (CN); Jianzhong Han, Chongqing (CN); Li Jin, Chongqing (CN)

(73) Assignee: UNITED MICROELECTRONICS CENTER CO., LTD, Chongqing (CN)

(21) Appl. No.: 17/943,135

(22) Filed: Sep. 12, 2022

Related U.S. Application Data
(63) Continuation of application No. PCT/CN2020/116503, filed on Sep. 21, 2020.

(30) Foreign Application Priority Data
May 22, 2020 (CN) 202010440056.4

(51) Int. Cl. G02B 6/34; H01L 27/12

(52) U.S. Cl. CPC G02B 6/34; H01L 27/1203; G02B 2006/12147

(57) ABSTRACT

A method for manufacturing a semiconductor device is provided. The method includes: providing a semiconductor-on-insulator substrate including a first substrate, a first insulating layer on the first substrate, and a semiconductor layer on the first insulating layer; patterning the semiconductor layer to form a grating coupler; forming one or more functional layer stacked with each other on a side of the semiconductor layer that faces away from the first insulating layer; bonding the one or more functional layer to a carrier substrate on a side of the one or more functional layer that faces away from the semiconductor layer; and completely removing the first substrate to provide, by the first insulating layer instead of the first substrate, an optical transmission channel between the grating coupler and an outside of the semiconductor device that is located on a side, facing away from the semiconductor layer, of the first insulating layer.

### CROSS REFERENCE TO RELATED APPLICATIONS

The present disclosure is a continuation of PCT International Application No. PCT/CN2020/116503, filed on Sep. 21, 2020, which claims priority to Chinese patent application No. 202010440056.4, filed on May 22, 2020. The entire contents of both applications are incorporated herein by reference in their entirety for all purposes.

### TECHNICAL FIELD

The present disclosure relates to the field of semiconductor technologies, and in particular to a method for manufacturing a semiconductor device, the semiconductor device, and a semiconductor integrated circuit.

### BACKGROUND

Silicon photonics technology uses an optical signal to replace an electrical signal to transmit data. It offers the advantages of high integration, high transmission rate, low power consumption, and the like, and therefore, the silicon photonics technology is considered as a promising technology. The development of silicon photonic chip-oriented technology based on a complementary metal oxide semiconductor (CMOS) technology is a mainstream research direction in the industry.

### SUMMARY

According to some embodiments of the present disclosure, a method for manufacturing a semiconductor device is provided, including: providing a semiconductor-on-insulator substrate including a first substrate, a first insulating layer on the first substrate, and a semiconductor layer on the first insulating layer; patterning the semiconductor layer to form a grating coupler; forming, on a side of the semiconductor layer that faces away from the first insulating layer, at least one functional layer stacked with each other; bonding, on a side of the at least one functional layer that faces away from the semiconductor layer, the at least one functional layer with a carrier substrate; and completely removing the first substrate, to provide, by the first insulating layer instead of the first substrate, an optical transmission channel between the grating coupler and an outside of the semiconductor device that is located on a side, facing away from the semiconductor layer, of the first insulating layer.

According to some embodiments of the present disclosure, a semiconductor device is provided, including: a first insulating layer; a semiconductor layer stacked with the first insulating layer, where the semiconductor layer includes a grating coupler; a carrier substrate arranged opposite to the semiconductor layer; and at least one functional layer stacked with each other and located between the semiconductor layer and the carrier substrate. No semiconductor material is provided on an entire surface of the first insulating layer that faces away from the semiconductor layer to provide, by the first insulating layer instead of the semiconductor material, an optical transmission channel between the grating coupler and an outside of the semiconductor device that is located on a side, facing away from the semiconductor layer, of the first insulating layer.

According to some embodiments of the present disclosure, a semiconductor integrated circuit is provided, including a semiconductor device, the semiconductor device comprising: a first insulating layer; a semiconductor layer stacked with the first insulating layer, wherein the semiconductor layer comprises a grating coupler; a carrier substrate arranged opposite to the semiconductor layer; and at least one functional layer stacked with each other and located between the semiconductor layer and the carrier substrate, wherein no semiconductor material is provided on an entire surface of the first insulating layer that faces away from the semiconductor layer to provide, by the first insulating layer instead of the semiconductor material, an optical transmission channel between the grating coupler and an outside of the semiconductor device that is located on a side, facing away from the semiconductor layer, of the first insulating layer.

These and other aspects of the present disclosure will be clear from the embodiments described below, and will be clarified with reference to the embodiments described below.

### BRIEF DESCRIPTION OF THE DRAWINGS

More details, features, and advantages of the present disclosure are disclosed in the following description of example embodiments in conjunction with the drawings, in which:

FIG. 1 is a flowchart of a method for manufacturing a semiconductor device according to an example embodiment of the present disclosure;

FIG. 2A to FIG. 2I are schematic diagrams of example structures formed through various steps of the method in FIG. 1 according to an example embodiment of the present disclosure;

FIG. 3 is a simplified block diagram of a semiconductor integrated circuit according to an example embodiment of the present disclosure; and

FIG. 4 is a simplified block diagram of a semiconductor integrated circuit according to another example embodiment of the present disclosure.

### DETAILED DESCRIPTION OF EMBODIMENTS

It is to be understood that although terms such as first, second and third may be used herein to describe various elements, components, areas, layers and/or part, these elements, components, areas, layers and/or part should not be limited by these terms. These terms are merely used to distinguish one element, component, area, layer or part from another. Therefore, a first element, component, area, layer or part discussed below may be referred to as a second element, component, area, layer or part without departing from the teaching of the present disclosure.

Spatially relative terms such as “under”, “below”, “lower”, “beneath”, “above” and “upper” may be used herein for ease of description to describe the relationship between one element or feature and another element(s) or feature(s) as illustrated in the figures. It will be understood that these spatially relative terms are intended to cover different orientations of a device in use or operation in addition to the orientations depicted in the figures. For example, if the device in the figures is turned over, an element described as being “below other elements or features” or “under other elements or features” or “beneath other elements or features” will be oriented to be “above other elements or features”. Thus, the exemplary terms “below” and “beneath” may cover both orientations “above” and “below”. Terms such as “before” or “ahead” and “after” or “then” may similarly be used, for example, to indicate the order in which light passes through elements. The device may be oriented in other ways (rotated by 90 degrees or in other orientations), and the spatially relative descriptors used herein are interpreted correspondingly. In addition, it will also be understood that when a layer is referred to as being “between two layers”, it may be the only layer between the two layers, or there may also be one or more intermediate layers.

The terms used herein are merely for the purpose of describing specific embodiments and are not intended to limit the present disclosure. As used herein, the singular forms “a”, “an”, and “the” are intended to include plural forms as well, unless otherwise explicitly indicted in the context. It is to be further understood that the terms “comprise” and/or “include”, when used in this specification, specify the presence of described features, entireties, steps, operations, elements and/or components, but do not exclude the presence or addition of one or more other features, entireties, steps, operations, elements, components and/or groups thereof. As used herein, the term “and/or” includes any and all combinations of one or more of the associated listed items, and the phrase “at least one of A and B” refers to only A, only B, or both A and B.

It is to be understood that when an element or a layer is referred to as being “on another element or layer”, “connected to another element or layer”, “coupled to another element or layer”, or “adjacent to another element or layer”, the element or layer may be directly on another element or layer, directly connected to another element or layer, directly coupled to another element or layer, or directly adjacent to another element or layer, or there may be an intermediate element or layer. On the contrary, when an element is referred to as being “directly on another element or layer”, “directly connected to another element or layer”, “directly coupled to another element or layer”, or “directly adjacent to another element or layer”, there is no intermediate element or layer. However, under no circumstances should “on” or “directly on” be interpreted as requiring one layer to completely cover the underlying layer.

Embodiments of the present disclosure are described herein with reference to schematic illustrations (and intermediate structures) of idealized embodiments of the present disclosure. Because of this, variations in an illustrated shape, for example as a result of manufacturing techniques and/or tolerances, should be expected. Therefore, the embodiments of the present disclosure should not be interpreted as being limited to a specific shape of an area illustrated herein, but should comprise shape deviations caused due to manufacturing, for example. Therefore, the area illustrated in a figure is schematic in nature, and the shape thereof is neither intended to illustrate the actual shape of the area of a device, nor to limit the scope of the present disclosure.

Unless otherwise defined, all terms (including technical and scientific terms) used herein have the same meanings as commonly understood by those of ordinary skill in the art to which the present disclosure belongs. It is to be further understood that the terms such as those defined in commonly used dictionaries should be interpreted as having meanings consistent with the meanings thereof in relevant fields and/or in the context of this specification, and will not be interpreted in an ideal or too formal sense, unless thus defined explicitly herein.

The inventors of the present application recognize that CMOS-compatible silicon photonics technology is facing some challenges. For example, in order to provide an optical transmission channel to a photonic device, a window opening process is used to etch a plurality of dielectric material layers in a silicon photonic chip, making large-scale application of the silicon photonics technology difficult. In addition, to achieve the improvement in electrical properties (for example, microwave loss), other aspects of properties (for example, structural stability) in the silicon photonic chip may be sacrificed.

The inventors of the present application further recognize that in the conventional CMOS-compatible silicon photonics technology, there are generally dielectric material (such as SiN or SiCN) layers between different metal layers, and that these dielectric material layers block the penetration of light undesirably. Therefore, it is required that a special photomask be provided to remove these dielectric material layers by etching, so as to open the area to be pervious to light (which is referred to as the “window opening process”). In the window opening process, the plurality of dielectric material layers are completely etched away, making large-scale application of the silicon photonics technology difficult. In addition, in the silicon photonic chip integrated with an active device, in order to achieve reduced microwave losses and improved impedance matching and refractive index matching, a solution has been proposed where through holes extending from the front side of the silicon photonic chip to the silicon substrate are provided and a part of the silicon substrate below the active device is hollowed out. However, this may cause the deterioration of the structural stability of the silicon photonic chip.

Embodiments of the present disclosure provide a semiconductor technology architecture, where after a front-side process is completed on a semiconductor-on-insulator substrate, the front side of the device is bonded to another carrier substrate, and then a substrate material under the insulator in the semiconductor-on-insulator substrate is completely removed. This provides a solution that may improve the optical properties and/or electrical properties of the obtained semiconductor device, making mass production of a semiconductor-based photonic devices possible.

As used herein, the term “substrate” may refer to a substrate of a cut wafer, or may refer to a substrate of an uncut wafer. Similarly, the terms “chip” and “bare die” are used interchangeably, unless such interchange may lead to a conflict. It should be understood that the term “layer” includes films and should not be construed as indicating vertical or horizontal thickness unless otherwise specified.

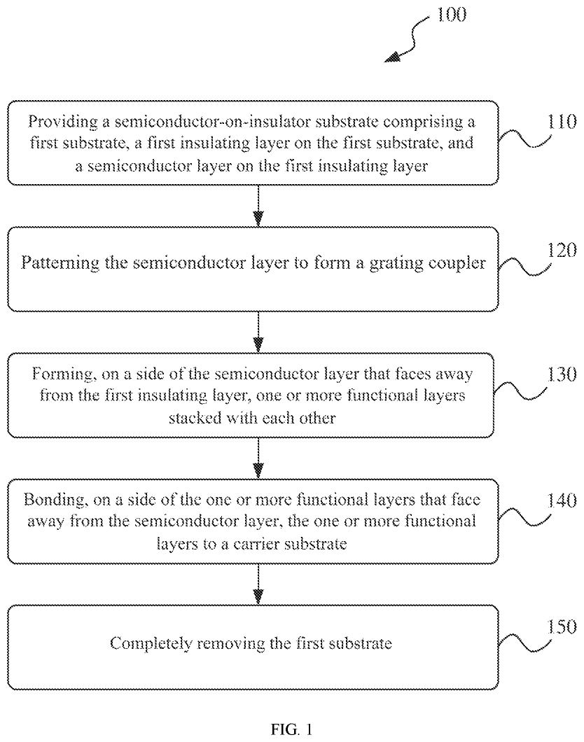

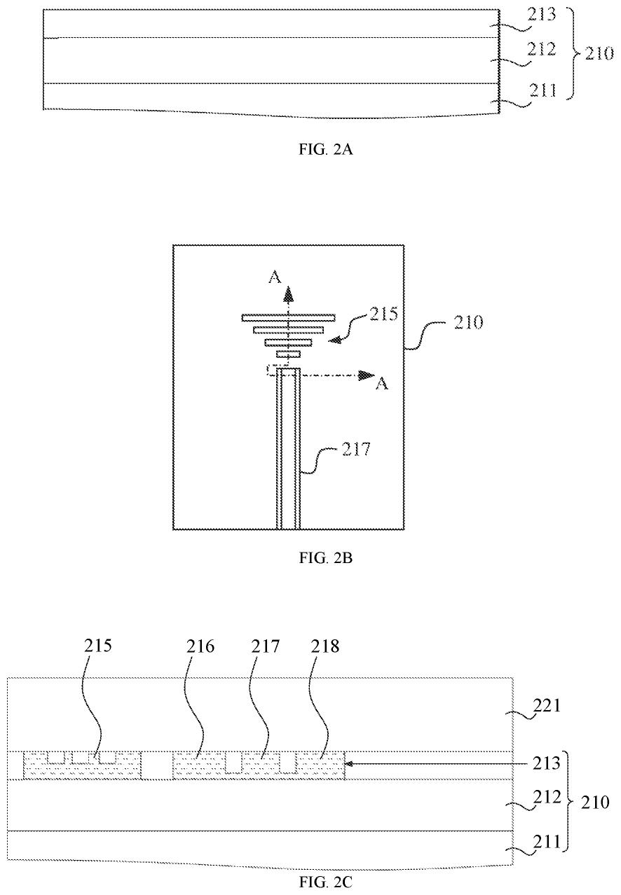

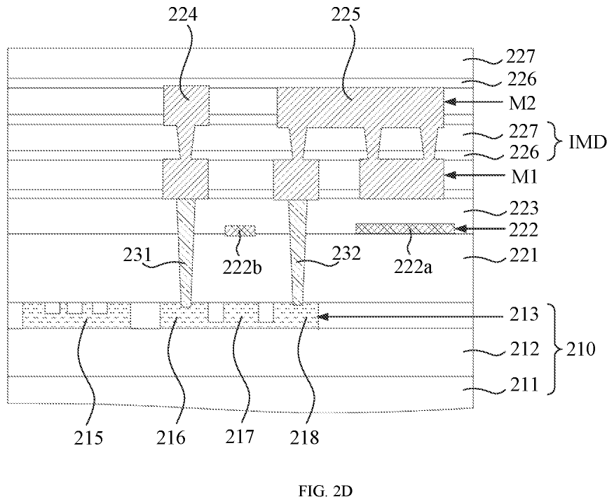

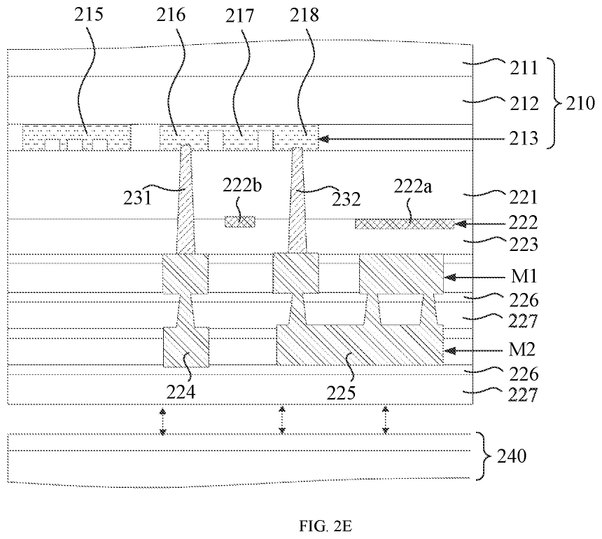

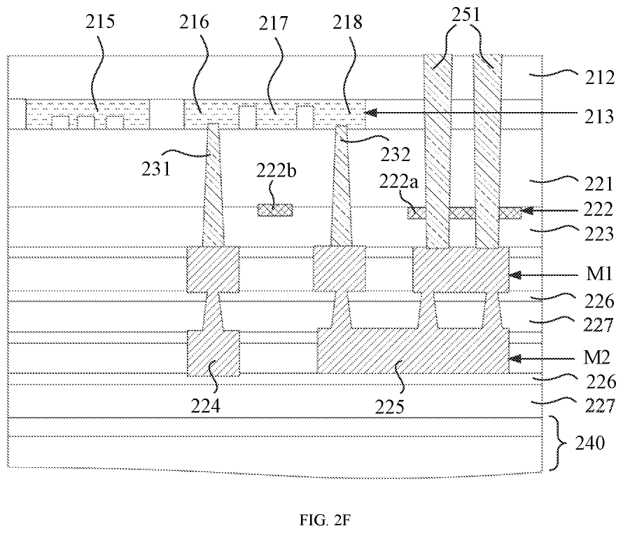

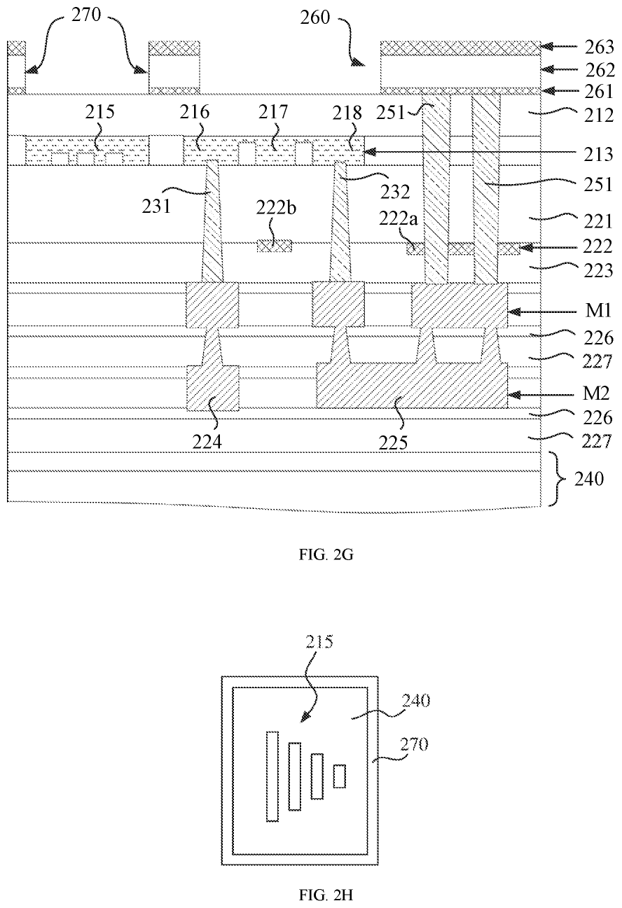

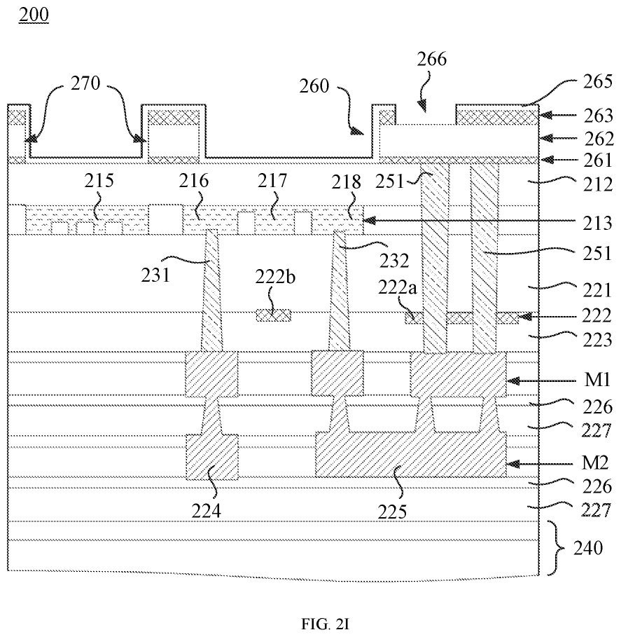

FIG. 1 is a flowchart of a method 100 for manufacturing a semiconductor device according to an example embodiment of the present disclosure, and FIG. 2A to FIG. 2I are schematic diagrams of example structures formed through various steps of the method 100. The method 100 is described below with reference to FIG. 1 and FIG. 2A to FIG. 2I.

In Step 110, a semiconductor-on-insulator substrate 210 is provided. As shown in FIG. 2A, the semiconductor-on-insulator substrate 210 includes a first substrate 211, a first insulating layer 212 on the first substrate 211, and a semiconductor layer 213 on the first insulating layer 212.

The substrate 210 may be any type of semiconductor-on-insulator substrate. In some embodiments, the semiconductor-on-insulator substrate 210 may be a silicon-on-insulator (SOI) substrate. The SOI substrate is readily available commercially and has good properties for an integrated photonic device. In such an embodiment, the first substrate 211 may be made of any suitable material (for example, silicon or germanium). In an example, the first substrate 211 may have a thickness of about 725 μm. The first insulating layer 212 may be made of any suitable insulating material (for example, silicon dioxide), and in some embodiments, the first insulating layer may be generally referred to as a buried oxide (BOX) layer. In an example, the first insulating layer 212 may have a thickness of about 2 μm. The semiconductor layer 213 may be referred to as a semiconductor device layer in which various semiconductor components are formed. In some embodiments, the semiconductor layer 213 may be made of silicon, but the present disclosure is not limited thereto. In an example, the semiconductor layer 213 may have a thickness of about 220 nm. In this context, referring to the orientation shown in FIG. 2A, the upper side of the first insulating layer 212 is referred to as a front side, and the lower side of the first insulating layer 212 is referred to as a back side.

In Step 120, the semiconductor layer 213 is patterned to form a grating coupler 215, for example, as shown in FIG. 2B and FIG. 2C. FIG. 2B schematically shows the arrangement of the semiconductor-on-insulator substrate 210 and the grating coupler 215 (and an optical waveguide 217 to be described later) when viewed down from the above. FIG. 2C schematically shows a cross-sectional view of an example structure that is obtained by cutting along line AA in FIG. 2B and formed in an optional step after Step 120, where in addition to the grating coupler 215 and the optical waveguide 217, additional optional features 216 and 218 (described later) are also shown. These optional features 216 and 218 are formed in the optional step after Step 120 and are not shown in FIG. 2B for clarity of illustration. It will be understood that the size and shape of the grating coupler 215 and the optical waveguide 217 are merely schematic and not necessarily proportionate.

In the embodiment where the semiconductor layer 213 is made of silicon, a silicon grating, namely the grating coupler 215, may be manufactured by using any suitable micro-fabrication process (for example, a bulk silicon fabrication technology). In the case of the bulk silicon fabrication technology, a part of the silicon material is selectively removed from the semiconductor (silicon) layer 213 according to a designed pattern, so as to form a designed micro three-dimensional structure, as shown in FIG. 2C. Specifically, the patterning process of the silicon grating may include etching, for example, wet etching and dry etching. Depending on etching rates for different crystallographic orientations in an etching solution, the wet etching may be classified as isotropic etching and anisotropic etching. The dry etching uses a physical method (for example, sputtering or ion etching) or a chemical method (for example, reactive ion etching). It will be understood that the grating coupler 215 shown in FIG. 2B and FIG. 2C is merely an example, and in other embodiments, the grating coupler 215 may be in any other suitable form.

In some embodiments, Step 120 may further include: patterning the semiconductor layer 213 to form an optical waveguide 217. The optical waveguide 217 may be optically coupled to the grating coupler 215, as shown in FIG. 2B and FIG. 2C. In the example of FIG. 2C, the optical waveguide 217 is formed as a rib optical waveguide, which includes a thicker inner ridge area and thinner outer ridge areas on both sides of the inner ridge area, but the present disclosure is not limited thereto. Additionally or alternatively, various other photonic devices, for example, a strip optical waveguide, an edge coupler, a waveguide crossing coupler, or a beam splitter, may be formed in the semiconductor layer 213. Various optical waveguide-based active devices, for example, an electro-optic modulator, a thermo-optic modulator, an electro-absorption modulator, or an optical detector, may also be formed.

After the semiconductor layer 213 is patterned, the removed part of the semiconductor layer 213 may be filled with suitable dielectric materials (for example, silicon dioxide) to prevent the semiconductor layer 213 from having voids. In an example, silicon dioxide may be deposited in the patterned semiconductor layer 213 by using a high density plasma (HDP) deposition process.

In Step 130, at least one functional layer stacked with each other is formed on the side of the semiconductor layer 213 that faces away from the first insulating layer 212, for example, as shown in FIG. 2D. As used herein, the term “functional layer” may refer to any suitable layer having electrical functions and/or optical functions. As an example rather than a limitation, the functional layer may include a conducting layer in which elements such as leads, electrodes, and/or antennas are formed and/or an insulating layer for providing insulation.

As shown in FIG. 2D, in some embodiments, Step 130 includes: on the side of the semiconductor layer 213 that faces away from the first insulating layer 212, forming a second insulating layer 221. The first insulating layer 212 and the second insulating layer 221 have a refractive index less than that of the semiconductor layer 213. Examples of the first insulating layer 212 and the second insulating layer 221 include, but are not limited to, silicon dioxide. In the embodiment where the optical waveguide 217 is patterned in the semiconductor layer 213, the first insulating layer 212 and the second insulating layer 221 may provide a total internal reflection condition for an optical signal in the optical waveguide 217, which improves the optical transmission efficiency. Silicon dioxide may further provide passivation for the semiconductor material (for example, silicon) in the semiconductor layer 213. In some examples, the second insulating layer 221 may be formed through plasma enhanced chemical vapor deposition (PECVD).

In addition to the second insulating layer 221, additional functional layers may also be formed according to specific device design requirements, which will be discussed later. For the descriptive purpose, some examples of the additional functional layers are listed as follows: a patterned conducting layer 222, an interlayer dielectric layer (IDL) 223, electrode structures 224 and 225 each including two metal layers (M1 and M2), and a plurality of intermetallic dielectric layers (IMDs) formed by stacking a first dielectric layer 226 and a second dielectric layer 227 alternately, as shown in FIG. 2D. These additional functional layers will be described in detail later in conjunction with specific active photonic devices.

In the example of FIG. 2D, the at least one functional layer includes the second dielectric layer 227 as an uppermost layer. The uppermost second dielectric layer 227 is also referred to as a third insulating layer in this context. The third insulating layer may be made of oxide (for example, silicon dioxide). In some embodiments, the thickness of the third insulating layer may be adjustable. This may be achieved, for example, by oxide deposition and planarization (for example, chemical mechanical polishing (CMP)). The third insulating layer with an adjustable thickness may be advantageous for some photonic devices. For example, for an edge coupler, the thickness of the cladding on the upper and lower sides of the semiconductor layer 213 will affect the coupling efficiency. The coupling efficiency of the edge coupler may be improved by adjusting the thickness (thickening or thinning) of the third insulating layer to a required thickness.

It will be understood that although FIG. 2D shows a plurality of example functional layers, the type and/or the number of functional layers to be formed may be determined according to specific applications and/or requirements.

In Step 140, on the side of the at least one functional layer that faces away from the semiconductor layer 213, the at least one functional layer is bonded to the carrier substrate 240, for example, as shown in FIG. 2E.

Step 140 may be implemented by a normal bonding process. In the example of FIG. 2E, the structure shown in FIG. 2D is now turned over, so that the third insulating layer 227 located in the uppermost layer in FIG. 2D is now located in the lowermost layer for being bonded to the carrier substrate 240. In some embodiments, the carrier substrate 240 may include a silicon substrate and a silicon dioxide layer on the silicon substrate. In this case, the third insulating layer 227 (for example, made of silicon dioxide) may be bonded to the silicon dioxide layer in the carrier substrate 240 through a low temperature bonding process. After the bonding is completed, a so-called back-side process may be performed on a structure of the semiconductor device shown in FIG. 2E.

In Step 150, the first substrate 211 is completely removed, so as to provide, by the first insulating layer 212 instead of the first substrate 211, an optical transmission channel between the grating coupler 215 and an outside of the semiconductor device that is located on the side, facing away from the semiconductor layer 213, of the first insulating layer 212, for example, as shown in FIG. 2F.

In some embodiments, Step 150 may be implemented by etching. In the embodiment where the first insulating layer 212 is made of silicon dioxide and the semiconductor layer 213 is made of silicon, the etching may be performed by using a tetramethylammonium hydroxide (TMAH) solution having a high selection ratio to silicon dioxide. Alternatively, the first substrate 211 may be thinned by wet etching, and then the first substrate 211 is completely removed by dry etching. In Step 150, the first substrate 211 is completely removed, and the first insulating layer 212 is exposed, as shown in FIG. 2F. FIG. 2F also shows some additional features (for example, back holes 251), which is further described later.

The complete removal of the first substrate 211 enables the grating coupler 215 in the semiconductor layer 213 to couple optical signals in and/or out from the back side without being affected by the front side dielectric material layers, thereby eliminating the need for performing the window opening process on the front side. As a result, on the front side of the grating coupler 215, metal wiring is no longer restricted, and a higher degree of design freedom is provided. Besides, the complete removal of the first substrate 211 may optimize the performance of the active device, for example, reduce microwave losses and improve impedance matching and refractive index matching. This provides additional advantages such as a simple process and a stable structure, compared with the related technologies of drilling a hole from the front side and then hollowing out a part of the substrate. In conclusion, the method 100 may provide a general process platform that facilitates mass production of the semiconductor photonic device.

In some embodiments, the method 100 may further include: after completely removing the first substrate 211, adjusting the thickness of the first insulating layer 212. In a case where a thicker first insulating layer 212 is required, the first insulating layer 212 may be thickened through an appropriate process. In an example, the material of the first insulating layer 212 is deposited on the first insulating layer 212, and then the deposited material is planarized, such that the first insulating layer 212 deposited with the material has a predetermined thickness. For example, the original first insulating layer 212 is made of silicon dioxide and has a thickness of 2 μm, in this case, if a thicker first insulating layer 212 is required, a silicon dioxide material may be deposited on the first insulating layer 212, and the deposited silicon dioxide is then planarized through a CMP process. The obtained first insulating layer 212 may have, for example, a thickness greater than 2 μm and less than or equal to 6 μm. Certainly, in a case where a thinner first insulating layer 212 is required, the first insulating layer 212 may be directly thinned to a required thickness through an appropriate process (for example, CMP). The first insulating layer 212 with an adjustable thickness may be advantageous for some specific applications. For example, for an edge coupler, the thickness of the cladding on the upper and lower sides of the semiconductor layer 213 will affect the coupling efficiency. By thickening the first insulating layer 212, the cladding on the upper and lower sides of the semiconductor layer 213 may have a substantially equal thickness, thereby improving the coupling efficiency of the edge coupler. For another example, for an active photonic device, a thinner first insulating layer 212 may be advantageous for heat dissipation.

In some embodiments, the method 100 may further include: forming a metal wiring layer 262 on the side of the first insulating layer 212 that faces away from the semiconductor layer 213. As shown in FIG. 2G, an orthogonal projection of the metal wiring layer 262 on the carrier substrate 240 does not overlap with an orthogonal projection of the grating coupler 215 on the carrier substrate 240. This ensures that the back side of the grating coupler 215 has no metal wiring, thereby preventing the coupling efficiency of the grating coupler 215 from being affected. The metal wiring layer 262 may be made of any suitable metal (for example, aluminum). In some embodiments, an anti-oxidation layer may be provided to prevent the metal wiring layer 262 from being oxidized. In the example of FIG. 2G, a first anti-oxidation layer 261, the metal wiring layer 262, and a second anti-oxidation layer 263 that are sequentially stacked are formed in a direction away from the first insulating layer 212, so that the metal wiring layer 262 is sandwiched between the upper and lower anti-oxidation layers 261 and 263. The anti-oxidation layers 261 and 263 may be made of any suitable material (for example, titanium nitride).

In some embodiments, the metal wiring layer 262 may include a metal isolation frame 270, as shown in FIG. 2G. FIG. 2G also shows some additional features, such as the anti-oxidation layers 261 and 263 described above. The metal isolation frame 270 is configured to prevent optical signals to/from the grating coupler 215 from interfering with other optical elements (for example, another grating). FIG. 2H schematically shows a top view of the metal isolation frame 270 and the grating coupler 215. As shown in FIG. 2H, an orthogonal projection of the metal isolation frame 270 on the carrier substrate 240 surrounds an orthogonal projection of the grating coupler 215 on the carrier substrate 240. The metal isolation frame 270 may be formed by patterning the metal wiring layer 262 (and potentially, the anti-oxidation layers 261 and 263). After the patterning, the side walls with the metal pattern (for example, the metal isolation frame 270) in the metal wiring layer 262 are exposed. In order to protect these side walls from being oxidized, the patterned metal wiring layer 262 may be further covered with a passivation layer 265, as shown in FIG. 2I. The passivation layer 265 may be made of any suitable material (for example, silicon dioxide).

Example embodiments of the method 100 are generally described above, where passive photonic devices (for example, the grating coupler 215 and/or the optical waveguide 217) are formed in the semiconductor layer 213. As a semiconductor photonic device process platform, the method 100 may be used to manufacture, based on the optical waveguide, various active photonic devices such as an electro-optic modulator and a thermo-optic modulator. Such embodiments of the method 100 are described below.

Referring back to FIG. 2C, the method 100 may further include: before the forming at least one functional layer stacked with each other, doping at least one of a first area 216 and a second area 218 of the semiconductor layer 213 that are respectively located on two sides of the optical waveguide 217. Orthogonal projections of the first area 216 and the second area 218 on the first insulating layer 212 adjoin an orthogonal projection of the optical waveguide 217 on the first insulating layer 212 and do not overlap with the orthogonal projection of the optical waveguide 217 on the first insulating layer 212. In some embodiments, the part (hereinafter referred to as a “modulated part”), located between the first area 216 and the second area 218, of the optical waveguide 217, may also be doped. Depending on a particular active photonic device to be formed, the first area 216 and the second area 218 (and in some embodiments, the modulated part of the optical waveguide 217) may be doped to a particular type (P-type or N-type, heavily doped or lightly doped). In an example embodiment where the electro-optic modulator is formed, the first area 216 and a sub-part of the modulated part that adjoin the first area 216 may be doped to form one of a P-type semiconductor and an N-type semiconductor, while the second area 218 and a sub-part of the modulated part that adjoin the second area 218 may be doped to form the other of the P-type semiconductor and the N-type semiconductor. Thus, the first area 216, the modulated part, and the second area 218 form a P-N junction. By applying a modulation signal to the first area 216 and the second area 218, the carrier concentration of the modulated part of the optical waveguide 217 may be changed. Therefore, the refractive index of the modulated part of the optical waveguide 217 is changed, thereby achieving the modulation of light. It will be understood that in other embodiments, the electro-optic modulator may be formed in another form by adopting another electrical structure, for example, an MOS capacitive modulator (where an oxide barrier layer is inserted into the modulated part of the optical waveguide 217 to form a capacitive structure between the first area 216 and the second area 218) or a PIN modulator (where the modulated part of the optical waveguide 217 is not doped). It will also be understood that the electro-optic modulator may use various optical structures, for example, a Mach-Zehnder interferometer (MZI) or a microring resonator (MRR). In an example embodiment where the thermo-optic modulator is formed, the first area 216 and the second area 218 may be doped to form a heavily doped N-type semiconductor, and the modulated part of the optical waveguide 217 may not be doped or may be doped to form a lightly doped N-type semiconductor. By applying a modulation signal to the first area 216 and the second area 218, the modulated part of the optical waveguide 217 may generate heat, thereby changing a phase of an optical field in the optical waveguide 217. It will be understood that in other embodiments, the thermo-optic modulator may be formed in another form by adopting another electrical structure. For example, only the first area 216 (or the second area 218) is lightly doped, and heat may be generated by applying a modulation signal on both ends of the first area 216 (or the second area 218). The generated heat may be transmitted to the modulated part of the optical waveguide 217 that is close to the first area 216 (or the second area 218), thereby changing a phase of an optical field in the optical waveguide 217. It will be understood that, whether the electro-optic modulator or the thermo-optic modulator is formed, the modulated part of the optical waveguide 217 may occupy only a section of the optical waveguide 217 along a light propagation direction.

Then, Step 130 of forming at least one functional layer stacked with each other may further include: forming a patterned conducting layer 222 on the side of the second insulating layer 221 that faces away from the semiconductor layer 213, as shown in FIG. 2D. As will be described below, the patterned conducting layer 222 may include different pattern parts to serve as an etching stop layer and/or a heat source (of the thermo-optic modulator). As shown in FIG. 2D, the patterned conducting layer 222 is covered with a dielectric material to form an interlayer dielectric layer 223.

Then, respective contact holes 231 and 232 that penetrate through the second insulating layer 221 (in the example of FIG. 2D, together with the interlayer dielectric layer 223) and are electrically connected to respective areas of the first area 216 and the second area 218 are formed. In this embodiment, the contact holes 231 and 232 may be filled with a conductive material (for example, tungsten or copper) to provide electrical connectivity.

Then, Step 130 of forming at least one functional layer stacked with each other may further include: forming respective electrode structures 224 and 225 on the side of the patterned conducting layer 222 that faces away from the second insulating layer 221. The respective electrode structures 224 and 225 are electrically connected to the respective contact holes 231 and 232, respectively, as shown in FIG. 2D. In the example of FIG. 2D, the electrode structures 224 and 225 each are formed by stacking two metal layers M1 and M2, but in other embodiments, the electrode structures 224 and 225 each may be formed by stacking fewer or more metal layers. Each metal layer M1 and M2 is electrically connected to each other through a through hole filled with the conductive material (for example, copper). The plurality of intermetallic dielectric layers (IMDs) formed by stacking the first dielectric layer 226 and the second dielectric layer 227 alternately provide electrical insulation between the metal layers. In an example, the first dielectric layer 226 may be made of silicon nitride, and the second dielectric layer 227 may be made of silicon dioxide. Silicon nitride has a better passivation effect, but after it is deposited, the defect density is higher at the interface. Silicon dioxide has a passivation effect inferior to silicon nitride, but after it is deposited, the defect density is lower at the interface. Therefore, a laminated structure of silicon nitride and silicon dioxide provides combined advantages of the two, thereby obtaining a good interlayer insulation effect.

Still referring to FIG. 2D, the patterned conducting layer 222 may include a respective first pattern part 222a corresponding to the respective electrode structures 224 and 225. Although only one first pattern part 222a corresponding to the electrode structure 225 is shown in the cross-sectional view in FIG. 2D, it will be understood that there may be another first pattern part 222a corresponding to the electrode structure 224 in another different cross section. An orthogonal projection of each of the respective first pattern parts 222a on the first insulating layer 212 partially overlaps with an orthogonal projection of the respective electrode structure of the respective electrode structures 224 and 225 on the first insulating layer 212, as shown in FIG. 2E.

To provide electrical connection to the electrode structures 224 and 225, a plurality of back holes 251 may be formed from the back side, as shown in FIG. 2F. In such embodiments, the method 100 further includes: forming a plurality of back holes 251 by etching, where the plurality of back holes extend from the surface of the first insulating layer 212 that faces away from the semiconductor layer 213 to the respective first pattern parts 222a. The respective first pattern parts 222a serve as an etching stop layer of the plurality of back holes 251. The etching continues, such that the plurality of back holes 251 penetrate the respective first pattern parts 222a and extend to the respective electrode structures 224 and 225. In this embodiment, the plurality of back holes 251 may be filled with a conductive material (for example, tungsten or copper) to provide electrical connectivity. Compared with a case where there is no etching stop layer, the first pattern part 222a provides advantageous advantages. If there is no first pattern part 222a, the etching process would stop directly at the metal layer M1, causing excessive loss of electrode materials and possible electrical defects. Due to the presence of the first pattern part 222a, the etching of the back holes 251 is completed in two stages, thereby allowing more precise control of the loss amount of the electrode materials and thus improving the product yield. In some examples, the first pattern part 222a may be about 150 nm away from the metal layer M1. It will be understood that, although only two back holes 251 corresponding to the electrode structure 225 are shown in the cross-sectional view in FIG. 2F, there may be other back holes 251 corresponding to the electrode structure 224 in another different cross section. It will be understood that the number of back holes 251 that connect to each electrode structure is not necessarily two, but there may be less than two or more than two back holes.

After the back holes 251 are formed, the method 100 may further include: forming respective pads 260 on the side of the first insulating layer 212 that faces away from the semiconductor layer 213, where the respective pads 260 are respectively electrically connected to the respective electrode structures 224 and 225 through respective back holes of the plurality of back holes 251. FIG. 2G and FIG. 2I show an example structure of the pads 260. In this example, the forming respective pads includes: forming a first anti-oxidation layer 261, a metal wiring layer 262, and a second anti-oxidation layer 263 that are sequentially stacked in a direction away from the first insulating layer 212; patterning the first anti-oxidation layer 261, the metal wiring layer 262, and the second anti-oxidation layer 263 to form respective pad areas; forming a passivation layer 265 covering the patterned second anti-oxidation layer 263; and removing a part of the passivation layer 265 and the second anti-oxidation layer 263 in each pad area to expose a part of the metal wiring layer 262 in the pad area. As shown in FIG. 2I, a window 266 is opened on the pad 260, so that an external modulation signal can be directly applied to the metal wiring layer 262 in the pad 260, and is transmitted to the first area 216 and the second area 218 in the semiconductor layer 213 through the back holes 251, the electrode structures 224 and 225, and the contact holes 231 and 232, thereby realizing the electro-optic modulation or thermo-optic modulation as described above. It will be understood that, although only the pad 260 corresponding to the electrode structure 225 is shown in the cross-sectional view in FIG. 2G, there may be another pad 260 corresponding to the electrode structure 224 in another different cross section.

In some embodiments, in place of the first pattern part 222a or in addition to the first pattern part 222a, the patterned conducting layer 222 may include a second pattern part 222b. An orthogonal projection of the second pattern part 222b on the first insulating layer 212 at least partially overlaps with the orthogonal projection of the optical waveguide 217 on the first insulating layer 212, as shown in FIG. 2D to FIG. 2G and FIG. 2I. In such embodiments, the second pattern part 222b and the optical waveguide 217 form a thermo-optic modulator, where the second pattern part 222b serves as a heat source that transfers heat to the optical waveguide 217 when a modulation signal is applied, thereby affecting the mode field distribution of the optical waveguide and realizing the phase change of an optical field. For clarity of illustration, the electrical connection to the second pattern part 222b is not shown in these figures, but it will be understood that the electrical connection to the second pattern part 222b may be provided by any suitable means (for example, similar to the metal interconnection to the electrode structures 224 and 225 and the back holes 251). In an example, the second pattern part 222b may be made of titanium nitride, but the present disclosure is not limited thereto. In the embodiment where the patterned conducting layer 222 includes both the first pattern part 222a and the second pattern part 222b, both the first pattern part 222a and the second pattern part 222b may be formed by patterning the conductive material layer at a time, thereby simplifying the process.

The method 100 and its various variations are described above with reference to FIG. 1 and FIG. 2A to FIG. 2I. It will be understood that these operations are not required to be performed in the particular order described, nor that all described operations must be performed to achieve desired results. For example, the step of forming the optical waveguide 217 may be performed before the step of forming the grating coupler 215. For another example, the step of forming the metal isolation frame 270 may be omitted.

Embodiments of the method for manufacturing a semiconductor device have been described, and the structure of the obtained semiconductor device will be clear. Hereinafter, for the sake of completeness, example embodiments of the semiconductor device are described with reference to FIG. 2I. The embodiments of the semiconductor device provide the same or corresponding advantages as the embodiments of the method, and a detailed description of these advantages is omitted for the sake of conciseness.

As shown in FIG. 2I, the semiconductor device 200 includes: a first insulating layer 212, a semiconductor layer 213 stacked with the first insulating layer 212, a carrier substrate 240 arranged opposite to the semiconductor layer 213, and at least one functional layer stacked with each other between the semiconductor layer 213 and the carrier substrate 240. The semiconductor layer 213 includes a grating coupler 215. No semiconductor material is provided on the entire surface of the first insulating layer 212 that faces away from the semiconductor layer 213, so as to provide, by the first insulating layer 212 instead of the semiconductor material, an optical transmission channel between the grating coupler 215 and an outside of the semiconductor device 200 that is located on the side, facing away from the semiconductor layer 213, of the first insulating layer 212.

In some embodiments, the at least one functional layer may include: a second insulating layer 221 located on the side of the semiconductor layer 213 that faces away from the first insulating layer 212. The first insulating layer 212 and the second insulating layer 221 have a refractive index less than that of the semiconductor layer 213. The semiconductor layer 213 may further include an optical waveguide 217 optically coupled to the grating coupler 215.

In some embodiments, the at least one functional layer may further include: a patterned conducting layer 222 located on the side of the second insulating layer 221 that faces away from the semiconductor layer 213.

In some embodiments, the semiconductor layer 213 may include: a first doped area 216 and a second doped area 218 respectively located on two sides of the optical waveguide 217. Orthogonal projections of the first doped area 216 and the second doped area 218 on the first insulating layer 212 adjoin an orthogonal projection of the optical waveguide 217 on the first insulating layer 212 and do not overlap with the orthogonal projection of the optical waveguide 217 on the first insulating layer 212. The semiconductor device 200 may further include: respective contact holes 231 and 232 that penetrate through the second insulating layer 221 and are electrically connected to respective areas of the first doped area 216 and the second doped area 218. The at least one functional layer may further include: respective electrode structures 224 and 225 located on the side of the patterned conducting layer 222 that faces away from the second insulating layer 221. The respective electrode structures 224 and 225 are electrically connected to the respective contact holes 231 and 232. respectively.

In some embodiments, the patterned conducting layer 222 may include: respective first pattern parts 222a corresponding to the respective electrode structures 224 and 225. An orthogonal projection of each of the respective first pattern parts 222a on the first insulating layer 212 partially overlaps with an orthogonal projection of the respective electrode structure of the respective electrode structures 224 and 225 on the first insulating layer 212. The semiconductor device 200 may further include a plurality of back holes 251 and respective pads 260. The plurality of back holes 251 extend from the surface of the first insulating layer 212 that faces away from the semiconductor layer 213 to the respective electrode structures 224 and 225. The respective pads 260 are located on the side of the first insulating layer 212 that faces away from the semiconductor layer 213, and are respectively electrically connected to the respective electrode structures 224 and 225 through respective back holes of the plurality of back holes 251.

In some embodiments, the through pads 260 may include: a first anti-oxidation layer 261, a metal wiring layer 262, and a second anti-oxidation layer 263 that are sequentially stacked in a direction away from the first insulating layer 212. The semiconductor device 200 may further include: a passivation layer 265 covering the second anti-oxidation layer 263. The passivation layer 265 and the respective second anti-oxidation layer 263 in each pad are arranged with a window 266 to expose a part of the metal wiring layer 262 in the pad.

In some embodiments, the patterned conducting layer 222 may include a second pattern part 222b. An orthogonal projection of the second pattern part 222b on the first insulating layer 212 at least partially overlaps with the orthogonal projection of the optical waveguide 217 on the first insulating layer 212. In some examples, the first insulating layer 212 may have a thickness of 2 μm to 6 μm.

In some embodiments, the semiconductor layer 200 may further include a metal wiring layer 262. The metal wiring layer 262 is located on the side of the first insulating layer 212 that faces away from the semiconductor layer 213. An orthogonal projection of the metal wiring layer 262 on the carrier substrate 240 does not overlap with an orthogonal projection of the grating coupler 215 on the carrier substrate 240.

In some embodiments, the metal wiring layer 262 may include a metal isolation frame 270. An orthogonal projection of the metal isolation frame 270 on the carrier substrate 240 surrounds the orthogonal projection of the grating coupler 215 on the carrier substrate 240.

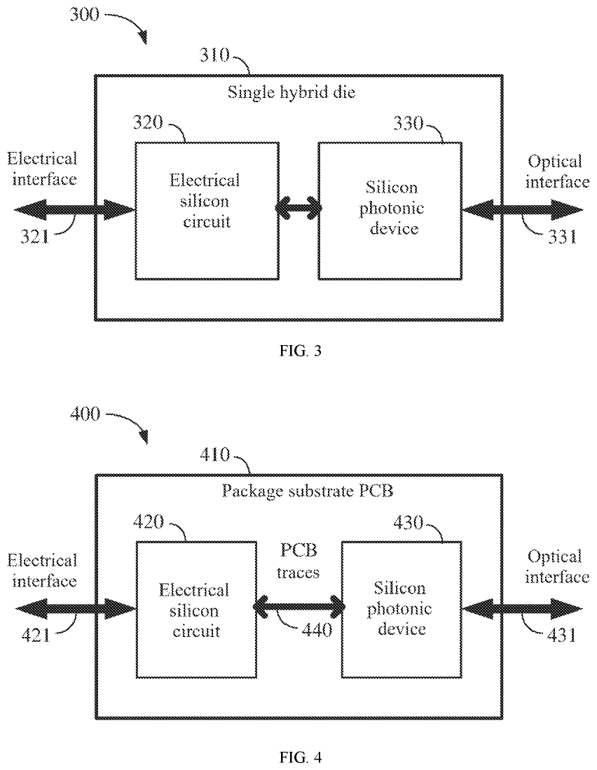

FIG. 3 is a simplified block diagram of a semiconductor integrated circuit 300 according to an example embodiment of the present disclosure, where both electronic devices and photonic devices are manufactured on a single hybrid die. In an example, the semiconductor integrated circuit 300 includes a single hybrid communication module made of a silicon material. The module includes a substrate member 310 having a surface area, an electrical silicon circuit 320 covering a first part of the surface area, a silicon photonic device 330 covering a second part of the surface area, a communication bus coupled between the electrical silicon circuit 320 and the silicon photonic device 330, an optical interface 331 coupled to the silicon photonic device 330, and an electrical interface 321 coupled to the electrical silicon circuit 320. The silicon photonic device 330 may embody any one of the semiconductor device 200 described above in FIG. 2I and its variations thereof.

FIG. 4 is a simplified block diagram of a semiconductor integrated circuit 400 according to an example embodiment of the present disclosure. In an example, the semiconductor integrated circuit 400 includes a single hybrid communication module. The module includes a substrate member 410 having a surface area, and the substrate member may be a printed circuit board (PCB) or another member. The module includes an electrical silicon circuit 420 covering a first part of the surface area, a silicon photonic device 430 covering a second part of the surface area, a communication bus 440 (for example, PCB traces) coupled between the electrical silicon circuit 420 and the silicon photonic device 430, an optical interface 431 coupled to the silicon photonic device 430, and an electrical interface 421 coupled to the electrical silicon circuit 420. The silicon photonic device 430 may embody any one of the semiconductor device 200 described above in FIG. 2I and its variations thereof.

Although the present disclosure has been illustrated and described in detail in the drawings and the foregoing description, such illustration and description should be considered illustrative and schematic, rather than limiting; and the present disclosure is not limited to the disclosed embodiments. By studying the drawings, the disclosure, and the appended claims, those skilled in the art can understand and implement modifications to the disclosed embodiments when practicing the claimed subject matter. In the claims, the word “comprising” does not exclude other elements or steps not listed, the indefinite article “a” or “an” does not exclude plural, and the term “a plurality of” means two or more. The mere fact that certain measures are recited in mutually different dependent claims does not indicate that a combination of these measures cannot be used to get benefit.

What is claimed is:

1. A method for manufacturing a semiconductor device, comprising:
providing a semiconductor-on-insulator substrate comprising a first substrate, a first insulating layer on the first substrate, and a semiconductor layer on the first insulating layer;
patterning the semiconductor layer to form a grating coupler;
forming, on a side of the semiconductor layer that faces away from the first insulating layer, one or more functional layers stacked with each other;
bonding, on a side of the one or more functional layers that face away from the semiconductor layer, the one or more functional layers to a carrier substrate; and
completely removing the first substrate to provide, by the first insulating layer instead of the first substrate, an optical transmission channel between the grating coupler and an outside of the semiconductor device that is located on a side, facing away from the semiconductor layer, of the first insulating layer.

2. The method according to claim 1,
wherein the forming of the one or more functional layers stacked with each other comprises forming a second insulating layer on the side of the semiconductor layer that faces away from the first insulating layer,
wherein the first insulating layer and the second insulating layer have a refractive index less than a refractive index of the semiconductor layer, and
wherein the method further comprises: prior to forming the one or more functional layers stacked with each other, patterning the semiconductor layer to form an optical waveguide optically coupled to the grating coupler.

3. The method according to claim 2, wherein forming the one or more functional layers stacked with each other further comprises:
forming a patterned conducting layer on a side of the second insulating layer that faces away from the semiconductor layer.

4. The method according to claim 3, further comprising:
prior to forming of the one or more functional layers stacked with each other, doping at least one of a first area and a second area of the semiconductor layer, the first area and the second area being located on respective sides of the optical waveguide, wherein orthogonal projections of the first area and the second area on the first insulating layer adjoin, and do not overlap with, an orthogonal projection of the optical waveguide on the first insulating layer; and
after the forming the patterned conducting layer, forming respective contact holes that penetrate through the second insulating layer and are respectively and electrically connected to respective ones of the first area and the second area,
wherein the forming one or more functional layers stacked with each other further comprises forming respective electrode structures on a side of the patterned conducting layer that faces away from the second insulating layer, wherein the respective electrode structures are electrically connected to the respective contact holes, respectively.

5. The method according to claim 4,
wherein the patterned conducting layer comprises respective first pattern parts corresponding to the respective electrode structures, wherein an orthogonal projection of each of the respective first pattern parts on the first insulating layer partially overlaps with an orthogonal projection of a corresponding one of the respective electrode structures on the first insulating layer; and
wherein the method further comprises:
forming a plurality of back holes by etching, wherein the plurality of back holes extend from a surface of the first insulating layer that faces away from the semiconductor layer to the respective first pattern parts, wherein the respective first pattern parts serve as an etching stop layer of the plurality of back holes;
continuing the etching such that the plurality of back holes penetrate through the respective first pattern parts and extend to the respective electrode structures; and
forming respective pads on the side of the first insulating layer that faces away from the semiconductor layer, wherein the respective pads are respectively and electrically connected to the respective electrode structures through corresponding ones of the plurality of back holes.

6. The method according to claim 5, wherein the forming respective pads comprises:
forming a first anti-oxidation layer, a metal wiring layer, and a second anti-oxidation layer that are sequentially stacked in a direction away from the first insulating layer;
patterning the first anti-oxidation layer, the metal wiring layer, and the second anti-oxidation layer to form respective pad areas;
forming a passivation layer covering the patterned second anti-oxidation layer; and
removing a part of the passivation layer and the second anti-oxidation layer in each pad area to expose a part of the metal wiring layer in the pad area.

7. The method according to claim 3, wherein the patterned conducting layer comprises a second pattern part, wherein an orthogonal projection of the second pattern part on the first insulating layer at least partially overlaps with an orthogonal projection of the optical waveguide on the first insulating layer.

8. The method according to claim 1,
wherein the one or more functional layers comprise a third insulating layer for being bonded to the carrier substrate, and
wherein the method further comprises: prior to bonding the one or more functional layers to the carrier substrate, adjusting a thickness of the third insulating layer.

9. The method according to claim 1, further comprising:
after completely removing the first substrate, adjusting a thickness of the first insulating layer.

10. A semiconductor device, comprising:
a first insulating layer;
a semiconductor layer stacked with the first insulating layer, wherein the semiconductor layer comprises a grating coupler;
a carrier substrate arranged opposite to the semiconductor layer; and
one or more functional layers stacked with each other and located between the semiconductor layer and the carrier substrate,
wherein no semiconductor material is provided on an entire surface of the first insulating layer that faces away from the semiconductor layer, such that the first insulating layer, instead of the semiconductor material, provides an optical transmission channel between the grating coupler and an outside of the semiconductor device that is located on a side, facing away from the semiconductor layer, of the first insulating layer.

11. The semiconductor device according to claim 10,
wherein the one or more functional layers comprises a second insulating layer located on the side of the semiconductor layer that faces away from the first insulating layer,
wherein the first insulating layer and the second insulating layer have a refractive index less than a refractive index of the semiconductor layer, and
the semiconductor layer further comprises an optical waveguide optically coupled to the grating coupler.

12. The semiconductor device according to claim 11, wherein the one or more functional layers further comprise a patterned conducting layer located on a side of the second insulating layer that faces away from the semiconductor layer.

13. The semiconductor device according to claim 12,
wherein the semiconductor layer comprises a first doped area and a second doped area located on respective sides of the optical waveguide, wherein orthogonal projections of the first doped area and the second doped area on the first insulating layer adjoin, and do not overlap with, an orthogonal projection of the optical waveguide on the first insulating layer, and
wherein the semiconductor device further comprises respective contact holes that penetrate through the second insulating layer and are electrically connected to respective ones of the first doped area and the second doped area, and
wherein the one or more functional layers further comprise respective electrode structures located on a side of the patterned conducting layer that faces away from the second insulating layer, wherein the respective electrode structures are electrically connected to the respective contact holes, respectively.

14. The semiconductor device according to claim 13,
wherein the patterned conducting layer comprises respective first pattern parts corresponding to the respective electrode structures, wherein an orthogonal projection of each of the respective first pattern parts on the first insulating layer partially overlaps with an orthogonal projection of a corresponding one of the respective electrode structures on the first insulating layer, and
wherein the semiconductor device further comprises:
a plurality of back holes extending from a surface of the first insulating layer that faces away from the semiconductor layer to the respective electrode structures; and
respective pads located on the side of the first insulating layer that faces away from the semiconductor layer, wherein the respective pads are respectively electrically connected to the respective electrode structures through corresponding ones of the plurality of back holes.

15. The semiconductor device according to claim 14,
wherein the respective pads comprise a first anti-oxidation layer, a metal wiring layer, and a second anti-oxidation layer that are sequentially stacked in a direction away from the first insulating layer, and
wherein the semiconductor device further comprises a passivation layer covering the second anti-oxidation layer, wherein the passivation layer and the second anti-oxidation layer in each pad are provided with a window to expose a part of the metal wiring layer in the pad.

16. The semiconductor device according to claim 12, wherein the patterned conducting layer comprises a second pattern part, wherein an orthogonal projection of the second pattern part on the first insulating layer at least partially overlaps with an orthogonal projection of the optical waveguide on the first insulating layer.

17. The semiconductor device according to claim 10, wherein the first insulating layer has a thickness of 2 μm to 6 μm.

18. The semiconductor device according to claim 10, further comprising:
a metal wiring layer located on the side of the first insulating layer that faces away from the semiconductor layer, wherein an orthogonal projection of the metal wiring layer on the carrier substrate does not overlap with an orthogonal projection of the grating coupler on the carrier substrate.

19. The semiconductor device according to claim 18, wherein the metal wiring layer comprises:
a metal isolation frame, wherein an orthogonal projection of the metal isolation frame on the carrier substrate surrounds the orthogonal projection of the grating coupler on the carrier substrate.

20. A semiconductor integrated circuit comprising a semiconductor device, the semiconductor device comprising:
a first insulating layer;
a semiconductor layer stacked with the first insulating layer, wherein the semiconductor layer comprises a grating coupler;
a carrier substrate arranged opposite to the semiconductor layer; and
one or more functional layers stacked with each other and located between the semiconductor layer and the carrier substrate,
wherein no semiconductor material is provided on an entire surface of the first insulating layer that faces away from the semiconductor layer such that the first insulating layer, instead of the semiconductor material, provides an optical transmission channel between the grating coupler and an outside of the semiconductor device that is located on a side, facing away from the semiconductor layer, of the first insulating layer.
